(19) United States
(12) Patent Application Publication
(10) Pub. No.: US 2026/0107649 A1
(43) Pub. Date: Apr. 16, 2026

(54) Display Apparatus

(71) Applicant: LG Display Co., Ltd., Seoul (KR)

(72) Inventors: Daeyun Kim, Paju-si (KR); Hyunsoo Um, Paju-si (KR); Younghun Kim, Paju-si (KR)

(21) Appl. No.: 19/291,943

(22) Filed: Aug. 6, 2025

(30) Foreign Application Priority Data
Oct. 14, 2024 (KR) 10-2024-0139280

(51) Int. Cl. H10K 59/131

(52) U.S. Cl. CPC H10K 59/131

(57) ABSTRACT

A display apparatus includes a display panel including a substrate and a plurality of pads disposed on the substrate, a source film including a source board, and a plurality of leads disposed on the source board and corresponding to the plurality of pads, respectively, and an anisotropic conductive film disposed between the plurality of pads and the plurality of leads, wherein the plurality of pads and the plurality of leads are disposed to face each other and overlap each other in a thickness direction, and each of the plurality of leads includes a first base portion and a plurality of guide portions protruding from the first base portion toward the plurality of pads.

### CROSS REFERENCE TO RELATED APPLICATION

The present application claims priority to Republic of Korea Patent Application No. 10-2024-0139280, filed on October 14, 2024, which is hereby incorporated by reference in its entirety.

### BACKGROUND

### Field of Technology

The present specification relates to a display apparatus.

### Description of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle, a high contrast ratio, is lighter and thinner, and has less power consumption than the LCD because it does not require a separate backlight. In addition, there is an advantage in that the OLED display apparatus can drive at a low voltage, have a fast response time, and especially have the inexpensive manufacturing cost.

The OLED display apparatus may include a display panel, and a flexible film connected to the display panel via an anisotropic conductive film (ACF). The ACF may include a resin and a plurality of conductive balls dispersed in the resin.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

The present specification is directed to providing a display apparatus in which it is possible to improve pressure mark visual perception of a pad (or a lead).

The present specification is also directed to providing a display apparatus in which it is possible to easily collect conductive balls of an anisotropic conductive film.

The present specification is also directed to providing a display apparatus in which it is possible to suppress or prevent a short circuit between adjacent pads (or leads).

The present specification is also directed to providing a display apparatus in which it is possible to suppress or prevent a short circuit defect between adjacent pads (or leads), thereby ensuring reliability of a pad part.

Objects of the present specification are not limited to the above-described objects, and other technical objects may be inferred from the following embodiments.

According to one embodiment of the present specification, there is provided a display apparatus including a display panel including a substrate, and a plurality of pads disposed on the substrate, a source film including a source board, and a plurality of leads disposed on the source board and corresponding to the plurality of pads, respectively, and an anisotropic conductive film disposed between the plurality of pads and the plurality of leads, wherein the plurality of pads and the plurality of leads are disposed to face each other and overlap each other in a thickness direction, and each of the plurality of leads includes a first base portion and a plurality of guide portions protruding from the first base portion toward the plurality of pads.

According to another embodiment of the present specification, there is provided a display apparatus including a display panel including a substrate, and a plurality of pads disposed on the substrate, a source film including a source board, and a plurality of leads disposed on the source board and corresponding to the plurality of pads, respectively, and an anisotropic conductive film disposed between the plurality of pads and the plurality of leads, wherein the plurality of pads and the plurality of leads are disposed to face each other and overlap each other in a thickness direction, and each of the plurality of leads includes a first conductive layer and a second conductive layer different from the first conductive layer, and the first conductive layer includes a lead groove that is recessed from one surface facing the pad toward the other surface that is a surface opposite to the one surface in the thickness direction, and the second conductive layer is disposed in the lead groove.

According to the embodiments of the present specification, it is possible to improve pressure mark visual perception of the pad (or the lead).

According to the embodiments of the present specification, it is possible to easily collect the conductive balls of the anisotropic conductive film.

According to the embodiments of the present specification, it is possible to suppress or prevent a short circuit between adjacent pads (or leads).

According to the embodiments of the present specification, it is possible to suppress or prevent a short circuit defect between adjacent pads (or leads), thereby ensuring reliability of the pad part.

According to the embodiments of the present specification, it is possible to prevent or at least reduce a likelihood of a short circuit defect between adjacent pads, thereby suppressing or preventing reliability of the pad part of the display apparatus from being reduced, and furthermore, to enable the operation defect prevention, life extension, etc. of the display apparatus, thereby reducing production energy.

However, effects obtainable from the present specification are not limited to the above-described effects, and other effects that are not mentioned will be able to be clearly understood by those skilled in the art to which the present specification pertains based on the following description.

Detailed matters of other embodiments are included in the detailed description and accompanying drawings.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

FIG. 1 is a schematic view illustrating a display apparatus according to one embodiment.

FIG. 2 is a systematic exemplary view of the display apparatus according to one embodiment.

FIG. 3 is an exemplary view of a circuit constituting a sub-pixel in the display apparatus according to one embodiment.

FIG. 4 is a cross-sectional view of the sub-pixel according to one embodiment.

FIG. 5 is an enlarged view of area Q1 in FIG. 2 according to one embodiment.

FIG. 6 is a view illustrating a shape in which a display panel and a source film are separated in FIG. 5 according to one embodiment.

FIG. 7 is a cross-sectional view along line A-A’ in FIG. 5 according to one embodiment.

FIG. 8 is an enlarged view of a rear surface of the source film according to one embodiment.

FIG. 9 is a cross-sectional view along line B-B’ in FIG. 8 according to one embodiment.

FIG. 10 is a cross-sectional view along line C-C’ in FIG. 8 according to one embodiment.

FIG. 11 is a cross-sectional view along line D-D’ in FIG. 8 according to one embodiment.

FIGS. 12 and 13 are schematic views illustrating a process of attaching the display panel and the source film and schematic views illustrating collected conductive balls according to one embodiment.

FIG. 14 is a schematic view illustrating a flow of an anisotropic conductive film around a lead electrode and a lead line according to one embodiment.

FIG. 15 is a cross-sectional view of a display apparatus according to another embodiment.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

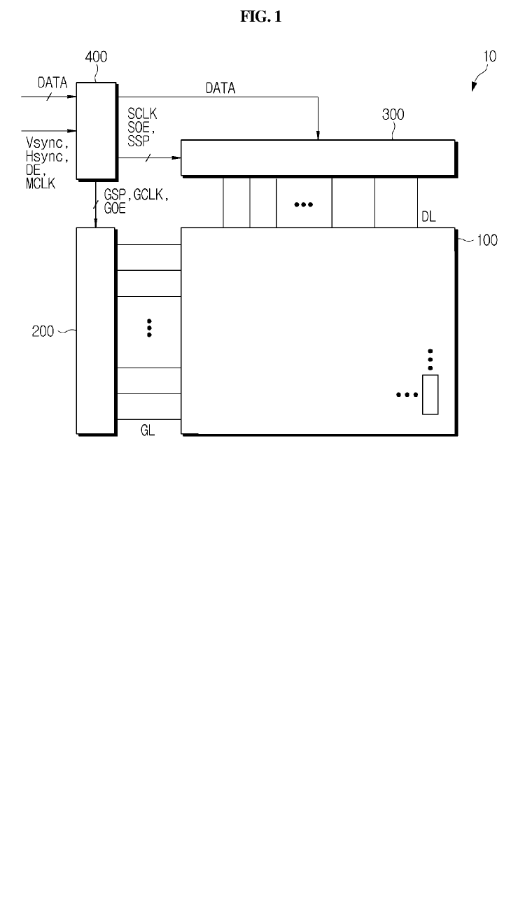

FIG. 1 is a schematic view illustrating a display apparatus according to one embodiment.

Referring to FIG. 1, a display apparatus 10 according to the first embodiment may include a display panel 100 in which a plurality of gate lines GL and data lines DL are connected and a plurality of sub-pixels SP are disposed, a gate driving circuit 200 for providing signals to the plurality of gate lines GL, a data driving circuit 300 for supplying a data voltage through the plurality of data lines DL, and a timing controller 400 for controlling the gate driving circuit 200 and the data driving circuit 300, and other circuit components. The gate driving circuit 200 may be a circuit for driving a plurality of gate lines GL, and the data driving circuit 300 may be a circuit for driving the plurality of data lines DL.

The display panel 100 displays images based on a scan signal transmitted from the gate driving circuit 200 through the plurality of gate lines GL and a data voltage transmitted from the data driving circuit 300 through the plurality of data lines DL.

In the case of a liquid crystal display apparatus, the display panel 100 may include a liquid crystal layer formed between two substrates and operate in any known mode of a twisted nematic (TN) mode, a vertical alignment (VA) mode, an in plane switching (IPS) mode, a fringe field switching (FFS) mode, etc. On the other hand, in the case of an organic light-emitting diode display apparatus, the display panel 100 may be implemented in a top emission manner, a bottom emission manner, a dual emission manner, etc.

The display panel 100 may include a plurality of pixels, each of which may be formed of sub-pixels SP with different colors, for example, a white sub-pixel, a red sub-pixel, a green sub-pixel, and a blue sub-pixel, and each sub-pixel SP may be defined by the plurality of data lines DL and the plurality of gate lines GL. A plurality of sub-pixels may be disposed in the display area DA of the display apparatus 10.

One sub-pixel SP may include a thin film transistor TFT disposed in an area formed by one data line DL and one gate line GL, a light-emitting element, such as a light-emitting diode that emits light according to a data voltage, a storage capacitor electrically connected to the light-emitting element to maintain a voltage, etc.

For example, when the display apparatus 10 having the resolution of 2,600 × 3,840 is formed of four sub-pixels SP of white W, red R, green G, and blue B, 2,600 gate lines GL may be provided, and 15,360 data lines DL (3,840 × 4 = 15,360) may be provided by data lines DL (= 3,840) each connected to each of four sub-pixels WRGB, and the sub-pixel SP may be disposed in each of areas formed by the gate lines GL and the data lines DL.

The gate driving circuit 200 is controlled by the timing controller 400 and controls driving timings of the plurality of sub-pixels SP by sequentially outputting scan signals to the plurality of gate lines GL disposed on the display panel 100.

The timing controller 400 may be implemented with various circuits or electronic components such as an integrated circuit (IC), a field programmable gate array (FPGA), an application specific integrated circuit (ASIC), a processor, and/or the like, without being limited thereto.

In the display apparatus 10 having the resolution of 2,600 × 3,840, a case in which scan signals are sequentially output from a first gate line to a 2,600th gate line with respect to 2,600 gate lines GL may be referred to as “2,600-phase driving.” Alternatively, as in a case in which scan signals are sequentially output from the first gate line to a fourth gate line and then the scan signals are sequentially output from a fifth gate line to an eighth gate line, a case in which a scan signal is sequentially output per four gate lines GL is referred to as “4-phase driving.” That is, a case in which a scan signal is sequentially output per N gate lines GL may be referred to as “N-phase driving.”

In this case, the gate driving circuit 200 may include one or more gate driving integrated circuits GDIC and may be located at only one side or both sides of the display panel 100 according to a driving method. Alternatively, the gate driving circuit 200 may be implemented in the form of a gate in panel (GIP) that is formed directly in a bezel area of the display panel 100, without being limited thereto. Alternatively, the gate driving circuit 200 may be disposed in the display area DA of the display panel 100.

The gate driving circuit 200 may be connected to the substrate 101 in an example where the gate driving circuit 200 is implemented by the chip-on-glass (COG) technique, the chip-on-film (COF) technique, or the like.

The data driving circuit 300 receives digital image data DATA from the timing controller 400 and converts the received digital image data DATA into an analog data voltage. Then, by outputting a data voltage to each data line DL according to the timing when the scan signal is applied through the gate line GL, each sub-pixel SP connected to the data line DL displays a light-emitting signal having brightness corresponding to the data voltage.

Likewise, the data driving circuit 300 may include one or more source driving integrated circuits SDIC, and the source driving integrated circuit SDIC may be connected to a bonding pad of the display panel 100 or disposed directly on the display panel 100 by a tape automated bonding (TAB) method or a chip on glass (COG) method or a chip on panel (COP) method.

In some cases, each source driving integrated circuit SDIC may be disposed integrally with the display panel 100. In addition, each source driving integrated circuit SDIC may be implemented by a chip on film (COF) method, and in this case, each source driving integrated circuit SDIC may be mounted on a circuit film and electrically connected to the data line DL of the display panel 100 through the circuit film.

The timing controller 400 supplies various control signals to the gate driving circuit 200 and the data driving circuit 300 and controls the operation of the gate driving circuit 200 and the data driving circuit 300. That is, the timing controller 400 controls the gate driving circuit 200 to output the scan signal according to the timing implemented in each frame and on the other hand, the timing controller 400 transmits the digital image data DATA received from the outside to the data driving circuit 300. For example, the timing controller 400 can receive input image data from outside (e.g., a host system) and supply digital image data DATA based on the input image data to the data driving circuit 300.

In this case, the timing controller 400 receives various timing signals including a vertical synchronization signal Vsync, a horizontal synchronization signal Hsync, a data enable signal DE, a main clock MCLK, etc. along with the digital image data DATA from the outside (e.g., a host system). Accordingly, the timing controller 400 generates the control signals using various timing signals received from the outside and transmits the control signals to the gate driving circuit 200 and the data driving circuit 300 to control the operation of the gate driving circuit 200 and the data driving circuit 300.

For example, the timing controller 400 outputs various gate control signals including a gate start pulse GSP, a gate clock GCLK, a gate output enable signal GOE, etc. to control the gate driving circuit 200. Here, the gate start pulse GSP controls the timing at which one or more gate driving integrated circuits GDIC constituting the gate driving circuit 200 start to operate. In addition, the gate clock GCLK is a clock signal input in common to the one or more gate driving integrated circuits GDIC and controls the shift timing of the scan signal. In addition, the gate output enable signal GOE specifies timing information of the one or more gate driving integrated circuits GDIC.

In addition, the timing controller 400 outputs various data control signals including a source start pulse SSP, a source sampling clock SCLK, a source output enable signal SOE, etc. to control the data driving circuit 300. Here, the source start pulse SSP controls the timing at which one or more source driving integrated circuits SDIC constituting the data driving circuit 300 start to sample data. The source sampling clock SCLK is a clock signal that controls the timing that samples data in the source driving integrated circuit SDIC. The source output enable signal SOE controls the output timing of the data driving circuit 300.

The display apparatus 10 may further include a power management integrated circuit for supplying various voltages or currents to the display panel 100, the gate driving circuit 200, the data driving circuit 300, etc. or controlling the various voltages or currents, which will be supplied.

Meanwhile, a light-emitting element may be disposed in each sub-pixel SP. For example, an OLED display apparatus may include a light-emitting element, such as a light-emitting diode, in each sub-pixel SP and display images by controlling a current flowing in the light-emitting element according to a data voltage.

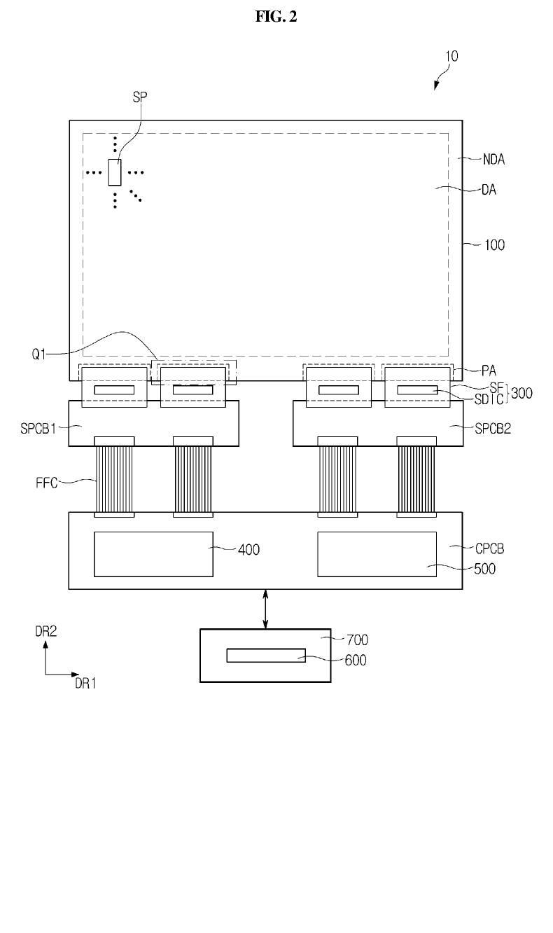

FIG. 2 is a systematic exemplary view of the display apparatus according to one embodiment.

Referring to FIGS. 1 and 2, a display apparatus 10 may be an apparatus including both a display function of displaying an image and a touch sensing function of sensing a user’s touch, but is not limited thereto. For example, the display apparatus 1 may include only one of the display function of displaying an image and the touch sensing function of sensing a user’s touch.

For example, in order to further provide a touch sensing function, as well as an image display function, the display apparatus 10 may further include at least one touch sensor, and a touch sensing circuit capable of detecting the occurrence of a touch event by a touch object such as a finger, a pen, or the like, or detecting a corresponding touch location (or touch coordinates), by sensing the touch sensor, and the like.

The display apparatus 10 may be an electroluminescent display apparatus or a micro light-emitting diode display apparatus that includes a touch sensor. The electroluminescent display apparatus including the touch sensor may be an organic light-emitting diode (OLED) display apparatus, a quantum-dot light-emitting diode display apparatus, or an inorganic light-emitting diode display apparatus.

The display apparatus 10 may include a display area DA and a non-display area NDA. The display area DA may include a plurality of pixels and display an image by emitting light to the outside. The display area DA may further include a function of sensing a user’s touch. In this case, the display area DA may correspond to a touch sensing area, but is not limited thereto.

The non-display area NDA may not display an image because it does not emit light to the outside. The non-display area NDA may be located around the display area DA or may surround the display area DA, but the embodiments of the present specification are not limited thereto. A bezel area of the display apparatus 1 may be defined by the non-display area NDA, but the embodiments of the present specification are not limited thereto. For example, the non-display area NDA may include a bezel area or an edge area. The non-display area NDA may be an area outside of the display area DA.

The display apparatus 10 may further include a pad area PA. The pad area PA may be disposed in the non-display area NDA.

The pad area PA may overlap a source film SF. The pad area PA may be attached to the source film SF. That is, the display panel 100 and the source film SF may be attached through the pad area PA. The source film SF may be formed of a bendable flexible film, but is not limited thereto.

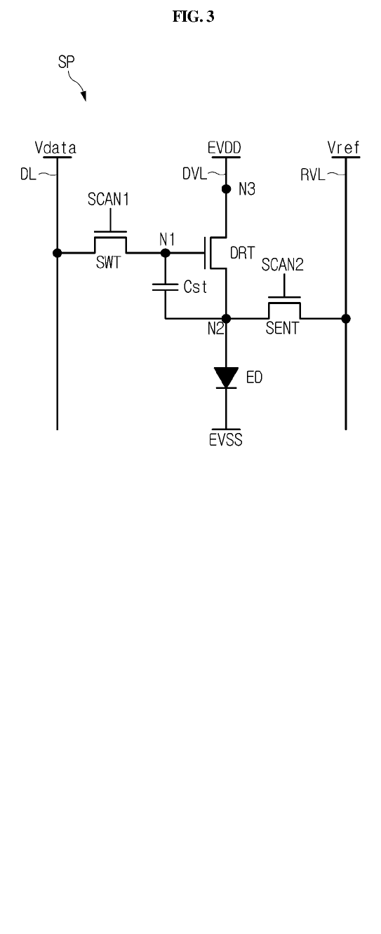

The pad area PA may include a plurality of pads. The pad area PA may include a low-potential pad that transmits a low-potential voltage (or a base voltage) EVSS (see FIG. 3), a high-potential pad that transmits a high-potential voltage (or a driving voltage) EVDD (see FIG. 3), a data pad connected to a data line DL, etc.

For example, the source driving integrated circuit SDIC included in the data driving circuit 300 can be implemented by various methods such as TAB, COG, COF, etc., and the gate driving circuit 200 can be implemented by various methods such as TAB, COG, COF, GIP, etc.

The display apparatus 10 according to one embodiment shows a case in which the source driving integrated circuit SDIC included in the data driving circuit 300 is implemented by the COF method among various methods (TAB, COG, COF, etc.), and the gate driving circuit 200 is implemented in the form of a GIP among various methods (TAB, COG, COF, GIP, etc.).

When the gate driving circuit 200 is implemented in the form of the GIP, a plurality of gate driving integrated circuits GDIC included in the gate driving circuit 200 may be formed directly in the bezel area of the display panel 100. In this case, the gate driving integrated circuit GDIC may receive various signals (a clock signal, a gate high signal, a gate low signal, etc.) required for generating a scan signal SCAN through gate driving-related signal lines disposed in the bezel area.

Likewise, each of one or more source driving integrated circuits SDIC included in the data driving circuit 300 may be mounted on the source film SF, and one side of the source film SF may be electrically connected to the display panel 100. In addition, lead electrodes (or leads) and lines for electrically connecting the source driving integrated circuit SDIC to the display panel 100 may be disposed on the source film SF.

The display apparatus 10 may include at least one source printed circuit board SPCB and a control printed circuit board CPCB on which control components and various electrical components are mounted for circuitry connection between the plurality of source driving integrated circuits SDIC and other devices.

In this case, one side of the source film SF on which the source driving integrated circuit SDIC is mounted may be electrically connected to the display panel 100, the other side of the source film SF on which the source driving integrated circuit SDIC is mounted may be connected to the at least one source printed circuit board SPCB. That is, the source film SF on which the source driving integrated circuit SDIC is mounted may have one side electrically connected to the display panel 100 and the other side electrically connected to the source printed circuit board SPCB. For example, a plurality of source films SF may be connected to one source printed circuit board SPCB, but is not limited thereto.

The timing controller 400 and a power management integrated circuit (PMIC) 500 may be mounted on the control printed circuit board CPCB. The timing controller 400 may control the operation of the data driving circuit 300 and the gate driving circuit 200. The timing controller 400 generates the control signals and transmits the control signals to the gate driving circuit 200 and the data driving circuit 300 to control the operation of the gate driving circuit 200 and the data driving circuit 300. The PMIC 500 may supply a driving voltage or current to the display panel 100, the data driving circuit 300, the gate driving circuit 200, etc. and control the supplied voltage or current.

The at least one source printed circuit board SPCB and the control printed circuit board CPCB may be connected circuitously through at least one connecting member, and the connecting member may include, for example, a flexible printed circuit (FPC), a flexible flat cable (FFC), etc. For example, the source printed circuit board SPCB may be provided a plurality of source printed circuit boards, and the plurality of source printed circuit boards SPCB may be connected to one control printed circuit board CPCB. For example, the plurality of source printed circuit boards SPCB may comprise a first source printed circuit board SPCB1 and a second source printed circuit board SPCB2, the first source printed circuit board SPCB1 and the second source printed circuit board SPCB2 may be connected to one control printed circuit board CPCB, but the embodiments of the present disclosure are not limited thereto. In this case, one source printed circuit board SPCB may be connected to the control printed circuit board CPCB through a plurality of flexible flat cables FFC. FIG. 2 exemplarily illustrates two source printed circuit boards SPCB1 and SPCB2, four flexible flat cables FFC, and one control printed circuit board CPCB, but the embodiments of the present specification are not limited thereto.

The display apparatus 10 may further include a set board 700 electrically connected to the control printed circuit board CPCB. In this case, the set board 700 may also be referred to as a power board. The set board 700 may include a main power management circuit (M-PMC) 600 for managing the overall power of the display apparatus 10. The M-PMC 600 may be interworked with the PMIC 500.

In the case of the display apparatus 10 having the above configuration, the driving voltage is generated from the set board 700 and transmitted to the PMIC 500 in the control printed circuit board CPCB. The PMIC 500 transmits a driving voltage required for display driving or characteristic value sensing to the source printed circuit board SPCB through the flexible printed circuit FPC or the flexible flat cable FFC. The driving voltage transmitted to the source printed circuit board SPCB is supplied to emit or sense a specific sub-pixel SP in the display panel 100 through the source driving integrated circuit SDIC.

In this case, each sub-pixel SP arranged on the display panel 100 in the display apparatus 10 may include a light-emitting element and a circuit element, such as a driving transistor for driving the light-emitting element, etc. In the example where the display apparatus 10 is a self-emission display apparatus, each of the plurality of sub-pixels SP may include a light emitting element.

The type and number of circuit elements forming each sub-pixel SP may be determined in any of various ways according to a providing function, a design method, etc.

FIG. 3 is an exemplary view of a circuit constituting a sub-pixel in the display apparatus according to one embodiment.

Referring to FIG. 3, in the display apparatus 10 according to one embodiment, the sub-pixel SP may include one or more transistors and a capacitor, and an organic light-emitting diode may be disposed as the light-emitting element ED.

For example, the sub-pixel SP may include a driving transistor DRT, a switching transistor SWT, a sensing transistor SENT, a storage capacitor Cst, and the light-emitting element ED.

The driving transistor DRT has a first node N1, a second node N2, and a third node N3. The first node N1 of the driving transistor DRT may be a gate node to which the data voltage Vdata is applied from the data driving circuit 300 through the data line DL when the switching transistor SWT is turned on. The second node N2 of the driving transistor DRT may be electrically connected to an anode electrode of the light-emitting element ED and may be a source node or a drain node. The third node N3 of the driving transistor DRT may be electrically connected to a driving voltage line DVL to which the driving voltage EVDD is applied and may be a drain node or a source node. The driving transistor DRT is turned on or off in response to the data voltage Vdata applied from the data driving circuit 300 through the data line DL.

In this case, during a display driving period, the driving voltage EVDD required to display an image may be supplied to the driving voltage line DVL, and for example, the driving voltage EVDD required to display an image may be 27 V, without being limited thereto.

The switching transistor SWT is electrically connected between the first node N1 of the driving transistor DRT and the data line DL and has a gate node connected to the gate line GL to operate according to the scan signal SCAN1 supplied through the gate line GL. The switching transistor SWT is turned on or off in response to the scan signal SCAN1 supplied through the gate line GL. In addition, when the switching transistor SWT is turned on, the operation of the driving transistor DRT is controlled by transmitting the data voltage Vdata supplied through the data line DL to the gate node of the driving transistor DRT.

The sensing transistor SENT is electrically connected between the second node N2 of the driving transistor DRT and a reference voltage line RVL and has a gate node connected to the gate line GL to operate according to a sense signal SCAN2 supplied through the gate line GL. The sensing transistor SENT is turned on or off in response to the sense signal SCAN2 supplied through the gate line GL. When the sensing transistor SENT is turned on, a sensing reference voltage Vref supplied through the reference voltage line RVL is transmitted to the second node N2 of the driving transistor DRT.

That is, a voltage of the first node N1 and a voltage of the second node N2 of the driving transistor DRT are controlled by controlling the switching transistor SWT and the sensing transistor SENT so that a current for driving the light-emitting element ED may be supplied.

The gate nodes of the switching transistor SWT and the sensing transistor SENT may be connected together to one gate line GL or connected to different gate lines GL. Here, a structure in which the switching transistor SWT and the sensing transistor SENT are connected to different gate lines GL is illustrated as an example, and in this case, the switching transistor SWT and the sensing transistor SENT may be independently controlled by the scan signal SCAN1 and the sense signal SCAN2 that are transmitted through the different gate lines GL.

On the other hand, when the switching transistor SWT and the sensing transistor SENT are connected to one gate line GL, the switching transistor SWT and the sensing transistor SENT may be simultaneously controlled by the scan signal SCAN1 or the sense signal SCAN2 transmitted through one gate line GL, and an aperture ratio of the sub-pixel SP can be increased. For example, when the switching transistor SWT and the sensing transistor SENT are connected to one gate line GL, they can be turned on or off simultaneously.

Meanwhile, the transistors disposed in the sub-pixel SP may be formed of both an n-type transistor and a p-type transistor, and here, the case in which the transistor is formed of the n-type transistor is illustrated as an example. Also, the transistors disposed in the sub-pixel SP may be formed of a p-type transistor.

The storage capacitor Cst is electrically connected between the first node N1 and the second node N2 of the driving transistor DRT and maintains the data voltage Vdata for one frame.

The storage capacitor Cst may be connected between the first node N1 and the third node N3 of the driving transistor DRT according to the type of the driving transistor DRT. The anode electrode of the light-emitting element ED may be electrically connected to the second node N2 of the driving transistor DRT, and the base voltage EVSS may be applied to a cathode electrode of the light-emitting element ED.

Here, the base voltage EVSS may be a ground voltage or a voltage higher or lower than the ground voltage. In addition, the base voltage EVSS may vary according to a driving state, and for example, the base voltage EVSS at the time of display driving and the base voltage EVSS at the time of sensing driving may be set differently.

The structure of the sub-pixel SP described above as an example is a 3T (transistor) 1C (capacitor) structure, which is only an example for description, and the sub-pixel SP may further include one or more transistors or in some cases, one or more capacitors. For example, 4T1C, 5T1C, 3T2C, 4T2C, 5T2C, 6T2C, 7T1C, 7T2C, 8T2C structures, etc. are also possible. Alternatively, each of the plurality of sub-pixels SP may be formed in the same structure, or some of the plurality of sub-pixels SP may be formed in different structures.

To effectively sense the characteristic value of the driving transistor DRT, such as a threshold voltage or mobility, the display apparatus 10 according to one embodiment may use a method of measuring a flowing current using a voltage charged in the storage capacitor Cst in a characteristic value sensing section of the driving transistor DRT, which is referred to as current sensing.

That is, by measuring the flowing current using the voltage charged in the storage capacitor Cst in the characteristic value sensing section of the driving transistor DRT, the characteristic value or a change in characteristic value of the driving transistor DRT in the sub-pixel SP may be identified.

In this case, since the reference voltage line RVL not only serves to transmit the reference voltage Vref but also serves as a sensing line for sensing the characteristic value of the driving transistor DRT in the sub-pixel SP, the reference voltage line RVL may be referred to as a sensing line.

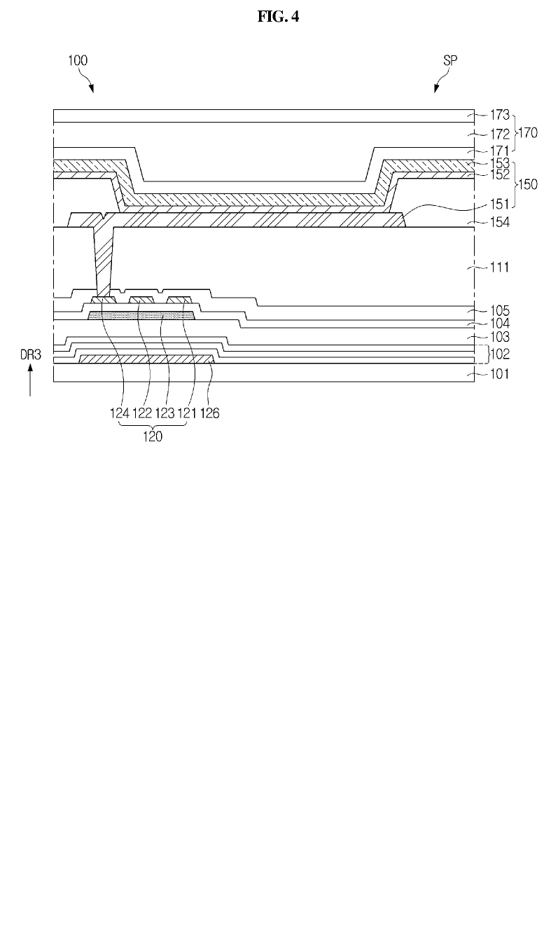

FIG. 4 is a cross-sectional view of the sub-pixel according to one embodiment. FIG. 4 illustrates a cross-sectional view of the sub-pixel SP of the display panel 100.

Referring to FIGS. 1 to 4, the display panel 100 may include a substrate 101, a first thin film transistor 120, a light-emitting part 150, and an encapsulation part 170.

The substrate 101 may be a rigid substrate, such as glass, quartz, etc., or a flexible substrate including a plastic material. For example, the substrate 101 may be a multi-substrate including a plurality of plastic materials, such as polyimide, etc., but the embodiments of the present specification are not limited thereto.

The substrate 101 may include a flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

A light-shielding layer 126 may be disposed on the substrate 101. The light-shielding layer 126 can prevent or at least reduce light from transmitting a first semiconductor layer 123 of the first thin film transistor 120. For example, the first semiconductor layer 123 may be disposed to overlap the light-shielding layer 126. The light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

A buffer layer 102 may be disposed on the light-shielding layer 126. The buffer layer 102 can minimize or reduce the diffusion of moisture or oxygen penetrating the substrate 101. The buffer layer 102 may be formed by alternately stacking silicon nitride (SiNx) and silicon oxide (SiOx) at least once, but the embodiments of the present specification are not limited thereto. Alternatively, the buffer layer 102 may be formed by inorganic film in a single layer, for example, the inorganic film in a single layer may be a silicon oxide (SiO) film or a silicon nitride (SiN) film.

A first insulating layer 103 may be disposed on the buffer layer 102. The first insulating layer 103 can prevent or at least reduce a likelihood of a short circuit between a component of the first thin film transistor 120 and the light-shielding layer 126. The first insulating layer 103 may be formed of the same material as the buffer layer 102, but the embodiments of the present specification are not limited thereto. For example, the first insulating layer 103 may be formed of an inorganic material, such as silicon nitride (SiNx) or silicon oxide (SiOx), but the embodiments of the present specification are not limited thereto. The first insulating layer 103 may be formed of the material different from that of the buffer layer 102, but the embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a material, such as amorphous silicon, low-temperature polycrystalline silicon, or polycrystalline silicon, but the embodiments of the present specification are not limited thereto. The first semiconductor layer 123 may include a channel area, a source area, and a drain area.

Since the low-temperature polycrystalline silicon semiconductor layer or the polycrystalline silicon semiconductor layer has higher mobility than the amorphous semiconductor layer and the oxide semiconductor layer, consumption power can be low and reliability can be excellent compared to the amorphous semiconductor layer and the oxide semiconductor layer. Accordingly, the driving transistor may be formed of the low-temperature polycrystalline silicon semiconductor layer or the polycrystalline silicon semiconductor layer, but the embodiments of the present specification are not limited thereto.

A second insulating layer 104 may be disposed on the first semiconductor layer 123. or example, the second insulating layer 104 may be disposed between the first semiconductor layer 123 and the first source electrode 121, a first gate electrode 122, and a first drain electrode 124 of the first thin film transistor 120. The second insulating layer 104 may be formed of the same material as the first insulating layer 103, but the embodiments of the present specification are not limited thereto. The second insulating layer 104 can prevent a short circuit between the first semiconductor layer 123 and another component of the first thin film transistor 120. The second insulating layer 104 may be a gate insulating layer, but is not limited thereto.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto. The first gate electrode 122 may be disposed along with a gate line, but the embodiments of the present specification are not limited thereto. The first source electrode 121 and the first drain electrode 124 may be formed on the same layer as the first gate electrode 122 and formed of the same conductive layer. The first source electrode 121 and the first drain electrode 124 may be electrically connected to the first semiconductor layer 123 through contact holes.

A third insulating layer 105 may be disposed on the first gate electrode 122, the first gate electrode 121, and the first drain electrode 124. The third insulating layer 105 may be formed of the same material as the first insulating layer 103 or the second insulating layer 104, but the embodiments of the present specification are not limited thereto. The third insulating layer 105 may be a passivation layer, but is not limited thereto.

A first protective layer 111 may be disposed on the third insulating layer 105. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present specification are not limited thereto.

The light-emitting part 150 may be disposed on the first protective layer 111. The light-emitting part 150 may include an anode electrode 151, an organic layer 152, and a cathode electrode 153.

The anode electrode 151 may be disposed on the first protective layer 111. The anode electrode 151 may be electrically connected to the first thin film transistor 120 through a contact hole formed in the first protective layer 111. For example, the anode electrode 151 may be electrically connected to the first drain electrode 124 of the first thin film transistor 120 through a contact hole formed in the first protective layer 111. The anode electrode 151 may be a reflective electrode that reflects light, but the embodiments of the present specification are not limited thereto. The anode electrode 151 may include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

The organic layer 152 may be disposed on the anode electrode 151. The organic layer 152 may include one or more light-emitting structures (or light-emitting elements or elements) stacked on the anode electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto. For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto.

The cathode electrode 153 may be disposed on the organic layer 152. The cathode electrode 153 may be a transparent electrode that transmits light, but the embodiments of the present specification are not limited thereto. For example, the cathode electrode 153 may include a transparent conductive material, such as indium tin oxide (ITO) or indium zinc oxide (IZO), or a metal that transmits visible light.

A bank 154 may be disposed to expose the anode electrode 151. The bank 154 may define an opening (or a light-emitting area) of the pixel and may be disposed to cover an edge portion of the anode electrode 151.

The bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be an opaque bank. When the bank 154 is formed of a material containing black pigment or black dye, it is possible to shield external light or light reflected from the outside, thereby further increasing the luminance of the display apparatus.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present specification are not limited thereto.

For example, the first encapsulation layer 171 and the third encapsulation layer 173 may include an inorganic insulating material capable of low-temperature deposition, such as silicon nitride (SiN), silicon oxide (SiO), silicon oxynitride (SiON) and aluminum oxide (Al2O3).

For example, the second encapsulation layer 172 may include an organic insulating material, such as acrylic resin, epoxy resin, polyimide, polyethylene and silicon oxycarbide (SiOC).

A touch layer that senses the user’s touch may be further disposed on the encapsulation part 170, but the embodiments of the present specification are not limited thereto.

Hereinafter, a pad electrode PD and a lead electrode RE that are disposed on the display panel 100 and the source film SF will be described in detail.

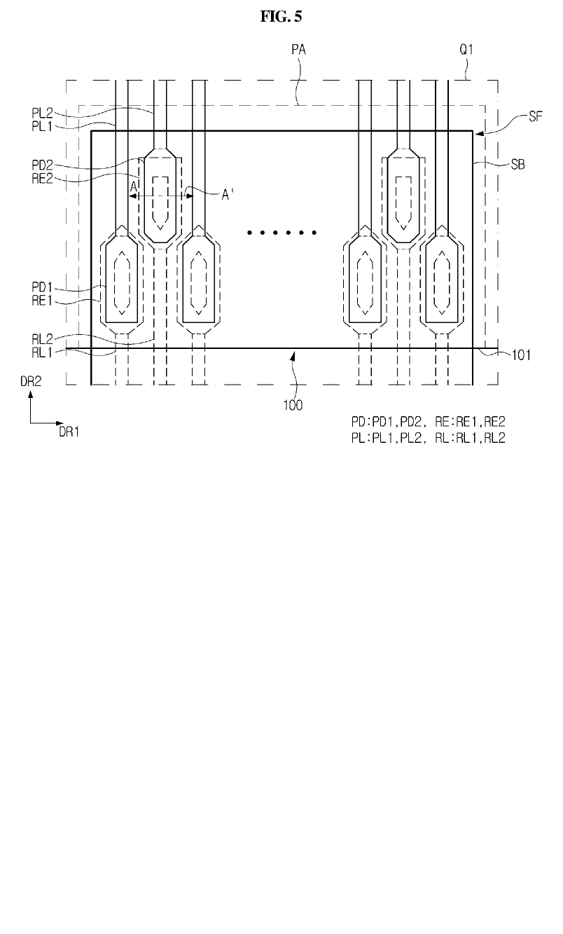

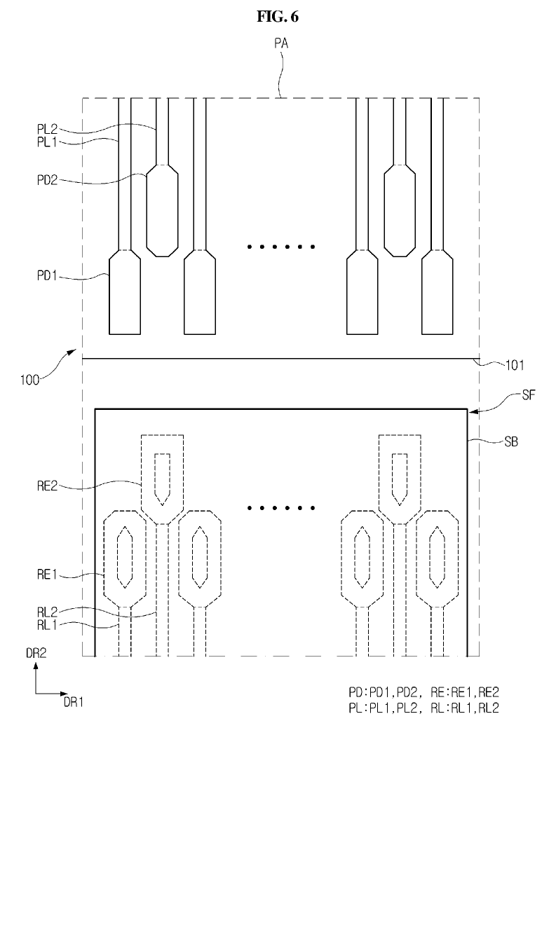

FIG. 5 is an enlarged view of area Q1 in FIG. 2 according to one embodiment. FIG. 6 is a view illustrating a shape in which a display panel and a source film are separated in FIG. 5 according to one embodiment.

Referring to FIGS. 5 and 6, the source film SF may include a source board SB, a plurality of lead electrodes RE (RE1 and RE2) disposed on the source board SB, and a lead line RL (RL1 and RL2) connected to the lead electrode RE.

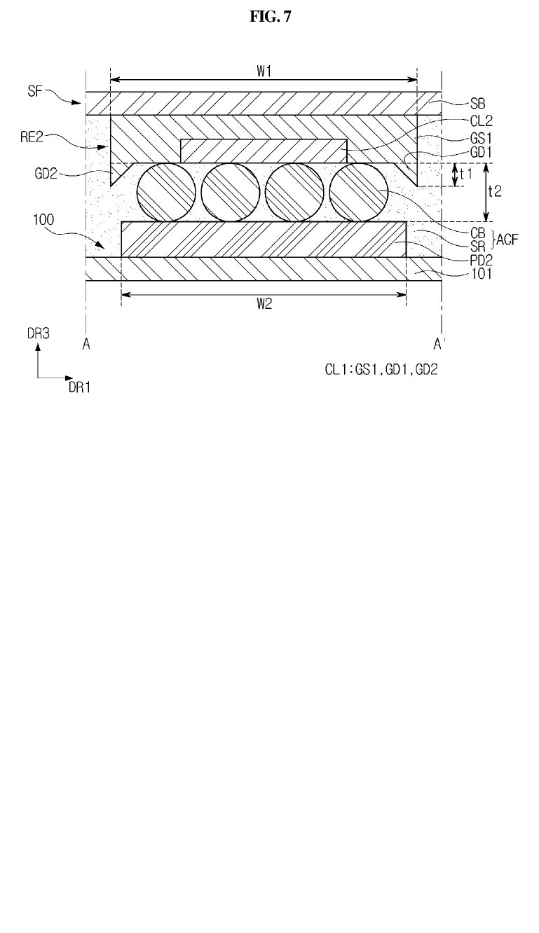

The display panel 100 may further include a plurality of pad electrodes PD (PD1 and PD2) disposed on the substrate 101 and a pad line PL (PL1 and PL2) connected to the pad electrodes PD. For convenience of description, FIG. 7 illustrates the plurality of pad electrodes PD disposed directly on the substrate 101, but the embodiments of the present specification are not limited thereto, and a plurality of insulating films, etc. may be further disposed between the pad electrode PD and the substrate 101.

The source board SB may be a flexible insulating film. The source board SB may include, for example, polycarbonate, polyethylene terephthalate, polyimide, polyamide, polyester, polyacrylate, polymethyl methacrylate, etc., but is not limited thereto.

A plurality of lead electrodes RE may be disposed on one surface of the source board SB. The one surface of the source board SB may refer to a surface facing the display panel 100. The plurality of lead electrodes RE may be disposed to face the display panel 100 on the one surface of the source board SB.

The plurality of lead electrodes RE may be electrically connected to the source driving integrated circuit SDIC through the lead line RL. The lead line RL may include the same material as the plurality of lead electrodes RE and may be formed integrally with the plurality of lead electrodes RE, but is not limited thereto.

The plurality of pad electrodes PD may be disposed on one surface of the substrate 101. The one surface of the substrate 101 may refer to a surface facing the source film SF. The plurality of pad electrodes PD may be disposed to face the source film SF on the one surface of the substrate 101. Accordingly, the plurality of lead electrodes RE may face the plurality of pad electrodes PD.

The plurality of lead electrodes RE may correspond to the plurality of pad electrodes PD, respectively. Each of the plurality of lead electrodes RE and each of the plurality of pad electrodes PD may at least partially overlap each other and may be electrically connected through a conductive ball CB in an overlapping area.

The plurality of lead electrodes RE may be repeatedly disposed in a first direction DR1. The plurality of lead electrodes RE may include a first lead electrode RE1 and a second lead electrode RE2 that are disposed in a staggered manner. The first lead electrode RE1 and the second lead electrode RE2 may be alternately and repeatedly disposed.

For example, the first lead electrode RE1 may correspond to the first pad electrode PD1, and the first lead electrode RE1 and the first pad electrode PD1 may at least partially overlap each other. For example, the second lead electrode RE2 may correspond to the second pad electrode PD2, and the second lead electrode RE2 and the second pad electrode PD2 may at least partially overlap each other.

The first lead electrode RE1 and the second lead electrode RE2 may be alternately and repeatedly disposed in the first direction DR1 and disposed in a staggered manner with respect to a second direction DR2. For example, the second lead electrode RE2 may be disposed to protrude to one side in the second direction DR2 more than the adjacent first lead electrode RE1. The second lead electrode RE2 may be disposed closer to an end side of the source film SF in the second direction DR2 than the adjacent first lead electrode RE1.

The first lead electrode RE1 and the second lead electrode RE2 may have a width in the first direction DR1 and extend in the second direction DR2. The first lead electrode RE1 and the second lead electrode RE2 may have different flat surface shapes.

The first lead electrode RE1 may have an area having a predetermined width, and a shape that extends from the area to one side and the other side in the second direction DR2 and has a width that narrows toward the one side and the other side in the second direction DR2. The second lead electrode RE2 may have an area having a predetermined width, and a shape that extends from the area to one side and the other side in the second direction DR2 and has a width that narrows toward the other side.

Specifically, the first lead electrode RE1 may be connected to the first lead line RL1 at the other side in the second direction DR2. The first lead electrode RE1 may include a first area having a predetermined width and a second area, a third area that narrow from the first area in the second direction DR2. The first lead electrode RE1 may include an area having a predetermined width, an area that extends from the area having the predetermined width to one side in the second direction DR2 and has a narrowing width, and an area that extends from the area having the predetermined width to the other side in the second direction DR2, has a narrowing width, and is connected to the first lead line RL1.

The second lead electrode RE2 may be connected to a second lead line RL2 at the other side in the second direction DR2. The second lead electrode RE2 may include a first area having a predetermined width and a second area that narrows from the first area in the second direction DR2. The second lead electrode RE2 may include an area having a predetermined width, and an area that extends from the area having the predetermined width to the other side in the second direction, has a narrowing width, and is connected to the first lead line RL1.

For example, the first lead electrode RE1 and the second lead electrode RE2 may have the different flat surface shape, but the embodiments of the present disclosure are not limited thereto.

However, the embodiments of the present specification are not limited thereto, and the first lead electrode RE1 and the second lead electrode RE2 may have the same flat surface shape. For example, both the first lead electrode RE1 and the second lead electrode RE2 may have the flat surface shape of the first lead electrode RE1 of FIG. 5 or the flat surface shape of the second lead electrode RE2 of FIG. 5.

In the area in which the display panel 100 overlaps the source film SF, arrangement locations of the plurality of pad electrodes PD may respectively correspond to arrangement locations of the corresponding lead electrodes RE. The flat surface shape of the plurality of pad electrodes PD may be substantially the same as the flat surface shape of the plurality of lead electrodes RE, but is not limited thereto.

For example, the first pad electrode PD1 and the second pad electrode PD2 may have the different flat surface shape, but the embodiments of the present disclosure are not limited thereto. Alternatively, both the first pad electrode PD1 and the second pad electrode PD2 may have the flat surface shape of the first lead electrode RE1 of FIG. 5 or the flat surface shape of the second lead electrode RE2 of FIG. 5.

Specifically, the plurality of lead electrodes PD may be repeatedly disposed in the first direction DR1. The plurality of pad electrodes PD may include a first pad electrode PD1 and a second pad electrode PD2 that are disposed in a staggered manner. The first pad electrode PD1 and the second pad electrode PD2 may be alternately and repeatedly disposed in the first direction DR1 and disposed in a staggered manner with respect to the second direction DR2.

The first pad electrode PD1 may correspond to the first lead electrode RE1, and the second pad electrode PD2 may correspond to the second lead electrode RE2.

An arrangement location of the first pad electrode PD1 may correspond to an arrangement location of the first lead electrode RE1, and an arrangement location of the second pad electrode PD2 may correspond to an arrangement location of the second lead electrode RE2.

The flat surface shape of the first pad electrode PD1 may be substantially the same as the flat surface shape of the second lead electrode RE2, and the flat surface shape of the second pad electrode PD2 may be substantially the same as the flat surface shape of the first lead electrode RE1. That is, the first pad electrode PD1 and the first lead electrode RE1 that correspond to each other may have different flat surface shapes, and the second pad electrode PD2 and the second lead electrode RE2 may have different flat surface shapes.

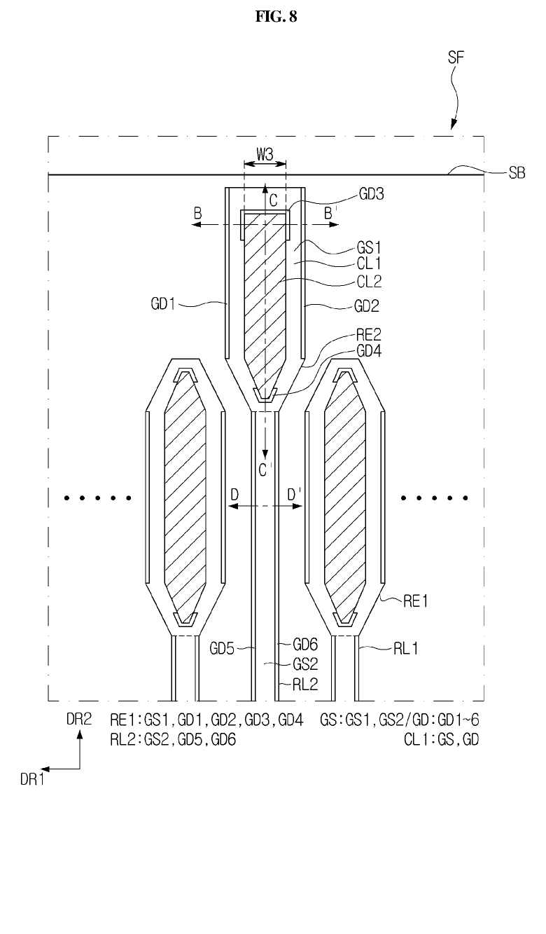

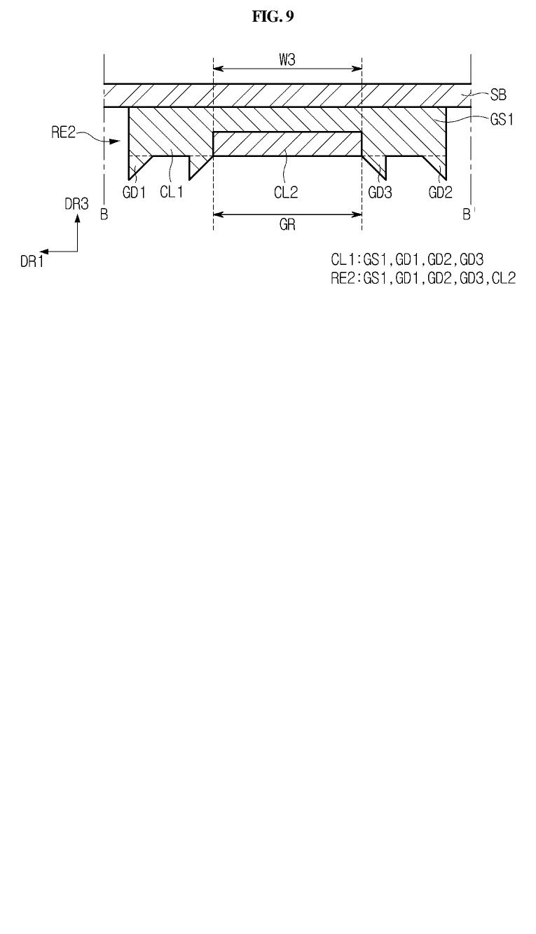

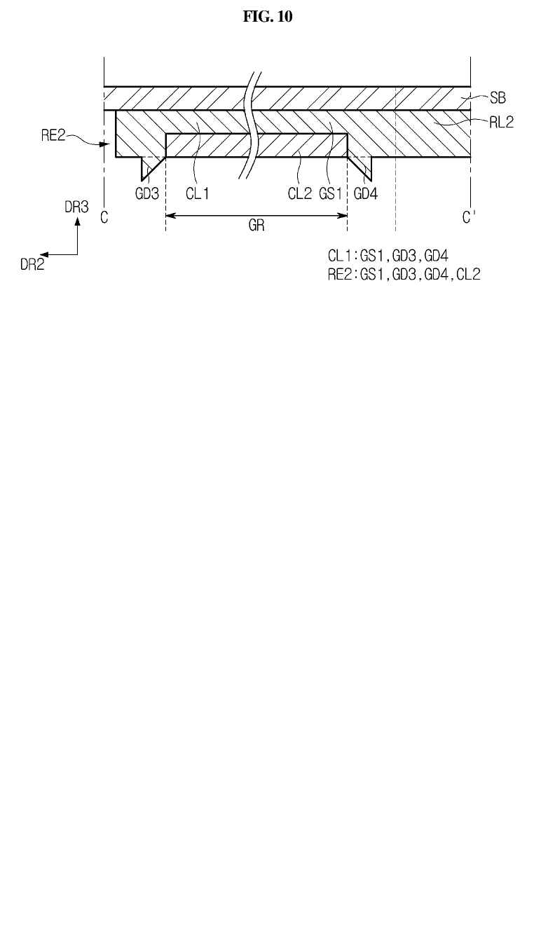

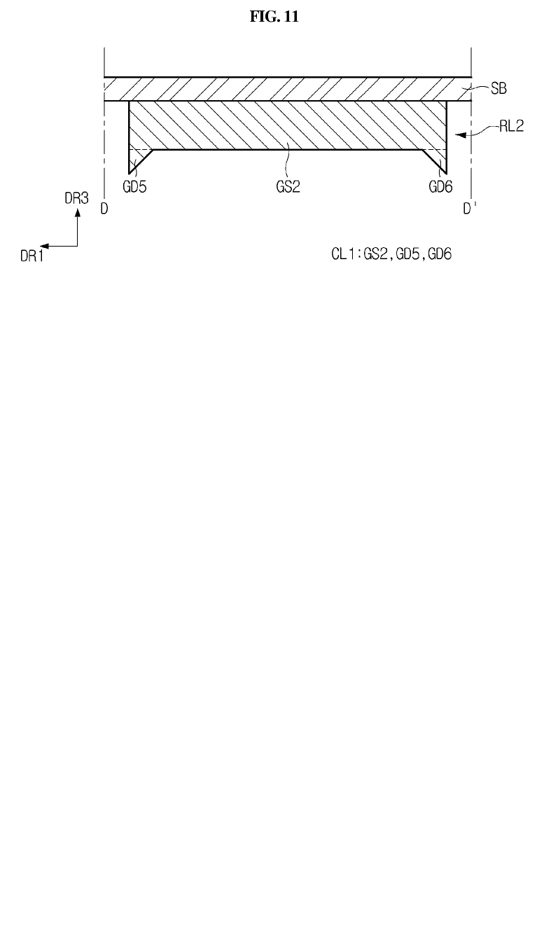

FIG. 7 is a cross-sectional view along line A-A’ in FIG. 5 according to one embodiment. FIG. 8 is an enlarged view of a rear surface of the source film according to one embodiment. FIG. 9 is a cross-sectional view along line B-B’ in FIG. 8 according to one embodiment. FIG. 10 is a cross-sectional view along line C-C’ in FIG. 8. FIG. 11 is a cross-sectional view along line D-D’ in FIG. 8 according to one embodiment.

FIG. 7 illustrates cross sections of the second lead electrode RE2 and the second pad electrode PD2, and FIGS. 9 to 11 illustrate a cross-section of the second lead electrode RE2, but the descriptions thereof may be applied to the first lead electrode RE1 and the first pad electrode PD1 in substantially the same manner.

Referring to FIGS. 5 and 7 to 11, the display apparatus 1 may further include an anisotropic conductive film ACF disposed between the source film SF and the display panel 100. The anisotropic conductive film ACF may also be disposed between the pad electrode PD and the lead electrode RE.

For example, the anisotropic conductive film ACF may be disposed between the first pad electrode PD1 and the first lead electrode RE1. The anisotropic conductive film ACF may also be disposed between the second pad electrode PD2 and the second lead electrode RE2.

The display panel 100 and the source film SF may be attached through the anisotropic conductive film ACF. Through the anisotropic conductive film ACF, the pad electrode PD and the lead electrode RE may be electrically connected.

For example, through the anisotropic conductive film ACF, the first pad electrode PD1 and the first lead electrode RE1 may be electrically connected, and the second pad electrode PD2 and the second lead electrode RE2 may be electrically connected.

The anisotropic conductive film ACF may include an adhesive member SR and one or more conductive balls CB.

The adhesive member SR may include a resin having an adhesive force. Since the adhesive member SR may be disposed between the source film SF and the display panel 100, the source film SF and the display panel 100 may be mutually adhered by the adhesive member SR.

The conductive ball CB may be disposed in the adhesive member SR. The conductive ball CB may include a conductive material. The conductive ball CB may be provided as a plurality of conductive balls and disposed in the adhesive member SR in a distributed manner.

The conductive ball CB may be disposed between the pad electrode PD and the lead electrode RE that overlap each other. The conductive ball CB may come into direct contact with the pad electrode PD and the lead electrode RE that overlap each other. The conductive ball CB may electrically connect the pad electrode PD to the lead electrode RE.

For example, the ve ball CB may be disposed between the first pad electrode PD1 and the first lead electrode RE1 that overlap each other, and between the second pad electrode PD2 and the second lead electrode RE2 that overlap each other.

The second lead electrode RE2 may include a first conductive layer CL1 and a second conductive layer CL2. The first conductive layer CL1 and the second conductive layer CL2 may include different materials. For example, the first conductive layer CL1 may include ITO, and the second conductive layer CL2 may include copper (Cu), but the embodiments of the present specification are not limited thereto.

The first conductive layer CL1 may define a lead groove GR that is recessed from one surface to the other surface. Here, the one surface of the first conductive layer CL1 may refer to a surface facing the pad electrode PD.

The second conductive layer CL2 may be disposed in the lead groove GR. The second conductive layer CL2 may be surrounded by the first conductive layer CL1 in a plan view.

The second lead line RL2 connected to the second lead electrode RE2 may be formed of the first conductive layer CL1, but is not limited thereto. The second conductive layer CL2 may be disposed only on the second lead electrode RE2 and may not be disposed on the second lead line RL2, but the embodiments of the present specification are not limited thereto.

The second conductive layer CL2 may extend in the second direction DR2 and have a third width W3 in the first direction DR1. The third width W3 may range from 24.4 µm to 30.4 µm or range from 20.0 µm to 35.0 µm.

When the third width W3 of the second conductive layer CL2 is smaller than the above range, the visibility of the conductive ball CB may not be sufficient. When the third width W3 of the second conductive layer CL2 is greater than the above range, the bezel of the display apparatus 10 may increase due to the areas of the lead electrode RE and the pad electrode PD.

When the second conductive layer CL2 includes copper (Cu) and has the width (the third width W3) within the above range, it is possible to sufficiently secure a pressure mark area in which a pressure mark of the conductive ball CB may be visible, thereby improving the visibility of the pressure mark of the conductive ball CB. Accordingly, the inspection as to whether the display panel 100 comes into contact with the source film SF can be performed more easily, and inspection quality and reliability for the presence or absence of the contact can be improved. Furthermore, it is possible to minimize a contact quality risk between the panel 100 and the source film SF and improve the reliability of the display apparatus 1.

In addition, since the second conductive layer CL2 has the third width W3, is disposed on the second lead electrode RE2, and is not disposed on the second lead line RL2, it is possible to suppress or prevent an increase in a material required for the second conductive layer CL2. In addition, since the process for forming the second conductive layer CL2 may be performed only on the second lead electrode RE2, it is possible to further facilitate the process and reduce the process cost and process time.

The second lead electrode RE2 may further include a first base portion GS1 and a guide portion GD protruding from the first base portion GS1 toward the pad electrode PD. The first base portion GS1 and the guide portion GD may be formed of the first conductive layer CL1. The first base portion GS1 and the guide portion GD may be formed integrally, but are not limited thereto.

The guide portion GD may include first to fourth guide portions GD1, GD2, GD3, and GD4. The first to fourth guide portions GD1, GD2, GD3, and GD4 may be formed of the first conductive layer CL1.

The first base portion GS1 may be disposed on the source board SB and may provide a space in which the first to fourth guide portions GD1, GD2, GD3, and GD4 may be disposed. The first base portion GS1 and the first to fourth guide portions GD1, GD2, GD3, and GD4 may be formed in the thickness direction (the third direction DR3).

The first base portion GS1 and the first to fourth guide portions GD1, GD2, GD3, and GD4 may be formed of the first conductive layer CL1. The first base portion GS1 and the first to fourth guide portions GD1, GD2, GD3, and GD4 may be formed integrally, but are not limited thereto.

The first base portion GS1 may define the lead groove GR and surround the second conductive layer CL2. The flat surface shape of the first base portion GS1 may correspond to the flat surface shape of the second lead electrode RE2.

For example, the first base portion GS1 may define the lead groove GR and the second conductive layer CL2 may be disposed in the lead groove GR. The first base portion GS1 may surround the second conductive layer CL2.

The first guide portion GD1 and the second guide portion GD2 may be disposed at one side and the other side of the second lead electrode RE2 in the first direction DR1. The first guide portion GD1 and the second guide portion GD2 may be disposed at one side and the other side of the first base portion GS1 in the first direction DR1, respectively, and may extend in the second direction DR2. The first guide portion GD1 and the second guide portion GD2 may be patterned and separately disposed.

The first guide portion GD1 and the second guide portion GD2 may be disposed at an outer side of the second conductive layer CL2. The first guide portion GD1 and the second guide portion GD2 may not overlap the second conductive layer CL2. The first guide portion GD1 and the second guide portion GD2 may be spaced apart from each other with the second conductive layer CL2 disposed therebetween. In a plan view, the first guide portion GD1 and the second guide portion GD2 may be disposed at one side and the other side of the second conductive layer CL2 in the first direction DR1.

The first guide portion GD1 and the second guide portion GD2 may have an inclined surface that is inclined with respect to the thickness direction (the third direction DR3). The first guide portion GD1 and the second guide portion GD2 may have a thickness that decreases from an outer side to an inner side of the second lead electrode RE2. The first guide portion GD1 and the second guide portion GD2 may have a thickness that decreases toward the second conductive layer CL2 in a plan view.

In a plan view, the first guide portion GD1 and the second guide portion GD2 may have a thickness that decreases toward the second conductive layer CL2 in the first direction DR1, but the embodiments of the present disclosure are not limited thereto.

Specifically, a thickness of the first guide portion GD1 disposed at one side of the second lead electrode RE2 in the first direction DR1 may decrease from one side to the other side in the first direction DR1. Specifically, a thickness of the second guide portion GD2 disposed at the other side of the second lead electrode RE2 in the first direction DR1 may decrease from the other side to one side in the first direction DR1.

Specifically, a thickness of the first guide portion GD1 may decrease from one side away from the second conductive layer CL2 to the other side adjacent to the second conductive layer CL2 in the first direction DR1, but the embodiments of the present disclosure are not limited thereto. Specifically, a thickness of the second guide portion GD2 may decrease from one side away from the second conductive layer CL2 to the other side adjacent to the second conductive layer CL2 in the first direction DR1, but the embodiments of the present disclosure are not limited thereto.

The first guide portion GD1 and the second guide portion GD2 may have a first thickness t1. The first thickness t1 may refer to a maximum thickness that is a thickness of the thickest portions of the first guide portion GD1 and the second guide portion GD2.

The first thickness t1 may be smaller than 1/2 of a diameter t2 of the conductive ball CB, for example. When the first thickness t1 is greater than 1/2 of the diameter t2 of the conductive ball CB, the conductive ball CB may be excessively pushed into the second conductive layer CL2, thereby reducing the visibility of the pressure mark of the conductive ball CB around an edge of the second conductive layer CL2.

By including the first guide portion GD1 and the second guide portion GD2, the conductive ball CB may be collected so that multiple conductive balls CB may be disposed between the second lead electrode RE and the second pad electrode PD2 so that the second lead electrode RE2 and the second pad electrode PD2 may be electrically connected more easily.

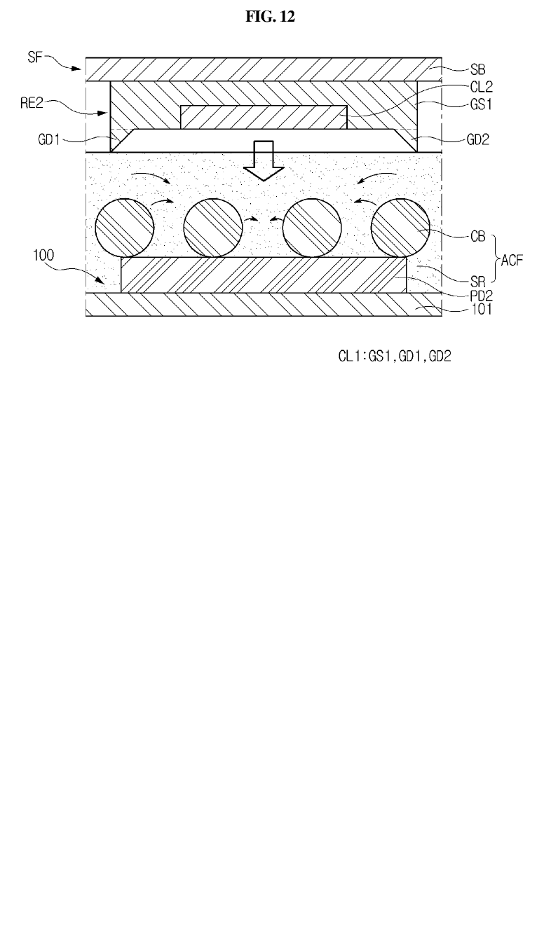

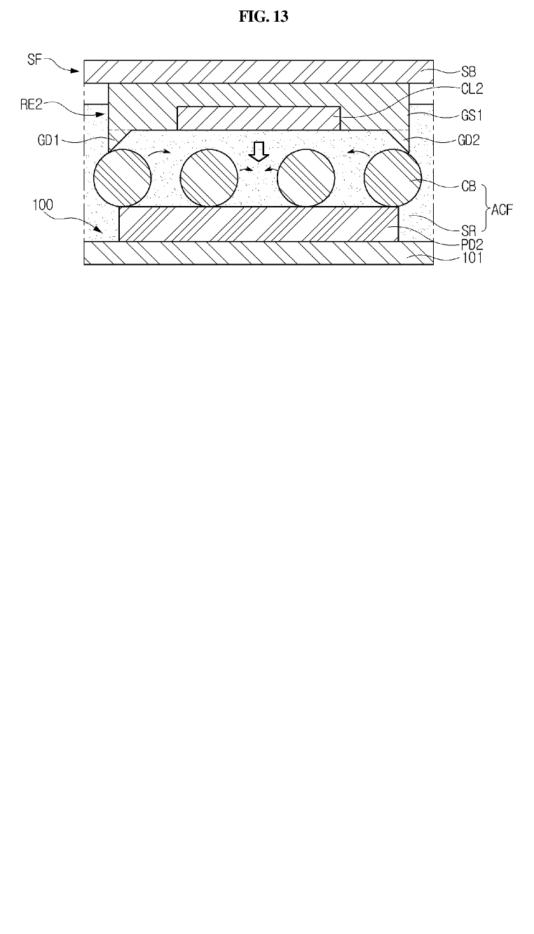

This will be described in more detail further with reference to FIGS. 12 and 13.

FIGS. 12 and 13 are schematic views illustrating a process of attaching the display panel and the source film and schematic views illustrating collected conductive balls according to one embodiment.

Referring further to FIGS. 12 and 13, the display panel 100 may be coated with the anisotropic conductive film ACF. The anisotropic conductive film ACF may include the adhesive member SR and the conductive balls CB disposed in the adhesive member SR in a distributed manner. For example, the conductive balls CB may be provided as a plurality of conductive balls.

The source film SF may approach toward the display panel 100 and may be compressed. In this process, the first guide portion GD1 and the second guide portion GD2 may form the flow of the adhesive member SR through a shape protruding toward the second pad electrode PD2. The adhesive member SR formed by the first guide portion GD1 and the second guide portion GD2 may be moved so that the conductive balls CB around the second pad electrode PD2 moves inward from the second pad electrode PD2.

As the compressing further progresses, the first guide portion GD1 and the second guide portion GD2 may come into physical contact with the conductive ball CB. Since the first guide portion GD1 and the second guide portion GD2 have an inclined surface that protrudes and is inclined inward, it is possible to suppress or prevent the conductive ball CB, which has come into physical contact with the first guide portion GD1 and the second guide portion GD2, from escaping from the space between the second lead electrode RE2 and the second pad electrode PD2. That is, the first guide portion GD1 and the second guide portion GD2 may collect the conductive ball CB, which has come into physical contact therewith, into the space between the second lead electrode RE2 and the second pad electrode PD2.

For example, the first guide portion GD1 and the second guide portion GD2 may collect the conductive ball CB, which has come into physical contact therewith, into the space between the first lead electrode RE1 and the first pad electrode PD1.

In addition, the second lead electrode RE2 may have a first width W1 in the first direction DR1, and the second pad electrode PD2 may have a second width W2 in the first direction DR1. The first width W1 may be greater than the second width W2. Side surfaces of one side and the other side of the second lead electrode RE2 in the first direction DR1 may protrude outward more than side surfaces of one side and the other side of the second pad electrode PD2. Accordingly, the conductive ball CB can be more easily collected.

Since the second lead electrode RE2 includes the first guide portion GD1 and the second guide portion GD2, more conductive balls CB may be disposed between the second lead electrode RE2 and the second pad electrode PD2 so that the second lead electrode RE2 and the second pad electrode PD2 may be electrically connected more easily.

Referring back to FIGS. 5 and 7 to 11, the third guide portion GD3 and the fourth guide portion GD4 may be respectively disposed at the one side and the other side of the second conductive layer CL2 in the second direction DR2. The third guide portion GD3 and the fourth guide portion GD4 may be patterned and separately disposed.

The third guide portion GD3 and the fourth guide portion GD4 may be disposed on the first base portion GS1 and disposed around the second conductive layer CL2. The third guide portion GD3 and the fourth guide portion GD4 may be disposed adjacent to the second conductive layer CL2 in a plan view. In a plan view, the third guide portion GD3 and the fourth guide portion GD4 may be disposed at one side and the other side of the second conductive layer CL2. The third guide portion GD3 and the fourth guide portion GD4 may be spaced apart from each other with the second conductive layer CL2 disposed therebetween.

The third guide portion GD3 and the fourth guide portion GD4 may be disposed on the first base portion GS1 and formed along a boundary between the first conductive layer CL1 and the second conductive layer CL2 in a plan view. The third guide portion GD3 and the fourth guide portion GD4 may not overlap the second conductive layer CL2.

The third guide portion GD3 and the fourth guide portion GD4 may be patterned and separated.

Each of the third guide portion GD3 and the fourth guide portion GD4 may be formed in an indented shape, but is not limited thereto. For example, the third guide portion GD3 may be formed in an indented shape from the other side to one side in the second direction DR2. The fourth guide portion GD4 may be formed in an indented shape from one side to the other side in the second direction DR2.

The third guide portion GD3 and the fourth guide portion GD4 may have an inclined surface that is inclined with respect to the thickness direction (the third direction DR3). The third guide portion GD3 and the fourth guide portion GD4 may have a thickness that decreases from an outer side to an inner side of the second lead electrode RE2. The third guide portion GD3 and the fourth guide portion GD4 may have a thickness that decreases toward the second conductive layer CL2 in a plan view.

Since the third guide portion GD3 and the fourth guide portion GD4 are disposed, it is possible to suppress or prevent the escape of the conductive ball CB of the anisotropic conductive film ACF, which flows into the second lead electrode RE2, and thus the conductive ball CB can be more smoothly collected, and more conductive balls CB can be disposed between the second lead electrode RE2 and the second pad electrode PD2 so that the second lead electrode RE2 and the second pad electrode PD2 may be electrically connected more easily.

Here, the inner side of the second lead electrode RE2 may refer to an area that is covered by the second lead electrode RE2 and/or an area that overlaps the second lead electrode RE2 in the thickness direction (the third direction DR3).

The second lead line RL2 may include a second base portion GS2 and a fifth guide portion GD5 and a sixth guide portion GD6 protruding from the second base portion GS2. The guide portion GD may further include the fifth guide portion GD5 and the sixth guide portion GD6.

The second base portion GS2 may be disposed on the source substrate SB and may provide a space in which the fifth guide portion GD5 and the sixth guide portion GD6 may be disposed. The flat surface shape of the second base portion GS2 may correspond to the flat surface shape of the second lead line RL2.

The fifth guide portion GD5 and the sixth guide portion GD6 may be disposed at one side and the other side of the second lead line RL2 in the second direction DR2. The fifth guide portion GD5 and the sixth guide portion GD6 may be patterned and separately disposed.

The fifth guide portion GD5 and the sixth guide portion GD6 may be disposed at one side and the other side of the first base portion GS2 in the second direction DR2, respectively, and may extend in the extension direction of the second lead line RL2.

The fifth guide portion GD5 may be disposed separately from the first guide portion GD1. The sixth guide portion GD6 may be disposed separately from the second guide portion GD2. A space into which the anisotropic conductive film ACF may be introduced may be provided between the fifth guide portion GD5 and the first guide portion GD1 and between the sixth guide portion GD6 and the second guide portion GD2. Accordingly, the anisotropic conductive film ACF disposed around the second lead electrode RE2 and the second lead line RL2 may be introduced.

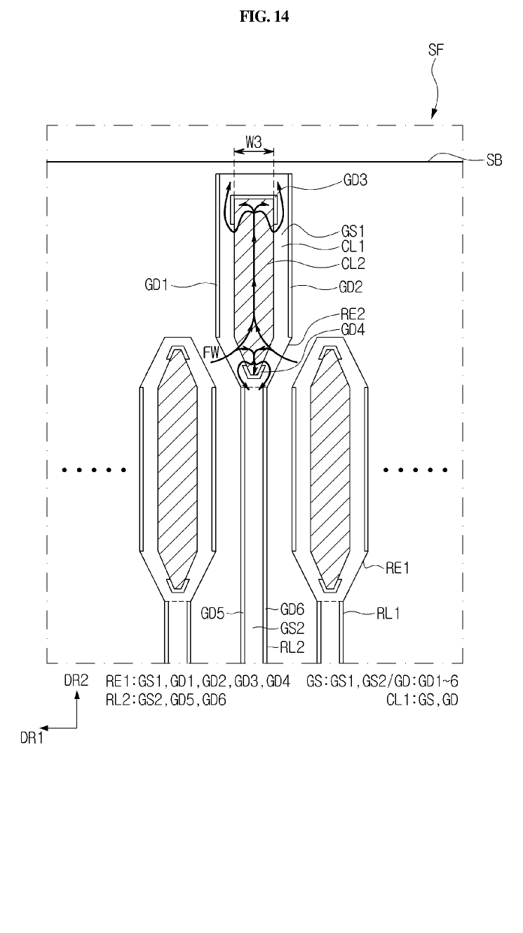

This will be described in more detail further with reference to FIG. 14.

FIG. 14 is a schematic view illustrating a flow of an anisotropic conductive film around a lead electrode and a lead line according to one embodiment.

Referring further to FIG. 14, during the process of compressing the display panel 100 and the source film SF of FIGS. 12 and 13, a flow FW of the anisotropic conductive film ACF pushed out by the first lead electrode RE1 and the first lead line RL1 may be formed around the second lead electrode RE2 and the second lead line RL2.

A space into which the anisotropic conductive film ACF may be introduced may be provided between the first guide portion GD1 of the adjacent second lead electrode RE2 and the fifth guide portion GD5 of the adjacent second lead line RL2 and between the second guide portion GD2 of the adjacent second lead electrode RE2 and the sixth guide portion GD6 of the adjacent second lead line RL2.

The anisotropic conductive film ACF pushed out by the first lead electrode RE1 and the first lead line RL1 may flow to an inside of the second lead electrode RE2 through a space between the first guide portion GD1 of the adjacent second lead electrode RE2 and the fifth guide portion GD5 of the adjacent second lead line RL2 and a space between the second guide portion GD2 of the adjacent second lead electrode RE2 and the sixth guide portion GD6 of the adjacent second lead line RL2.

Since the anisotropic conductive film ACF that has a flow FW that flows to the inside of the second lead electrode RE2 by the third guide portion GD3 and the fourth guide portion GD4 may have a longer flow path, the time for the anisotropic conductive film ACF to flow into the second lead electrode RE2 may be longer.

The escape of the conductive ball CB of the anisotropic conductive film ACF flowing to the inside of the second lead electrode RE2 can be suppressed or prevented by the third guide portion GD3 and the fourth guide portion GD4.

The adhesive member SR of the anisotropic conductive film ACF flowing to the inside of the second lead electrode RE2 may escape outward from the second lead electrode RE2 through the area between the guide portions GD, etc. For example, the adhesive member SR may escape to an area between the first guide portion GD1 and the third guide portion GD3, an area between the second guide portion GD2 and the third guide portion GD3, outward from the fourth guide portion GD4, an area between the fifth guide portion GD5 and the sixth guide portion GD6, etc.

By arranging the guide portion GD, more conductive balls CB can remain inside the second lead electrode RE2, and the conductive balls CB that may be disposed between the lead electrodes RE can be reduced.

Accordingly, electrical contact between the lead electrode RE and the pad electrode PD can be made more smoothly, and it is possible to suppress or prevent a short circuit caused by the conductive balls CB disposed between adjacent lead electrodes RE and between adjacent pad electrodes PD. Furthermore, it is possible to ensure the reliability of the pad part of the display apparatus 1, thereby suppressing or preventing an operation defect of the display apparatus 1, increasing the life of the display apparatus 1, and reducing production energy.

Hereinafter, other embodiments of the present specification will be described. For contents substantially the same as those described with reference to FIGS. 1 to 14 among components included in other embodiments, the same reference numerals are given, and the overlapping contents may be omitted or briefly described.

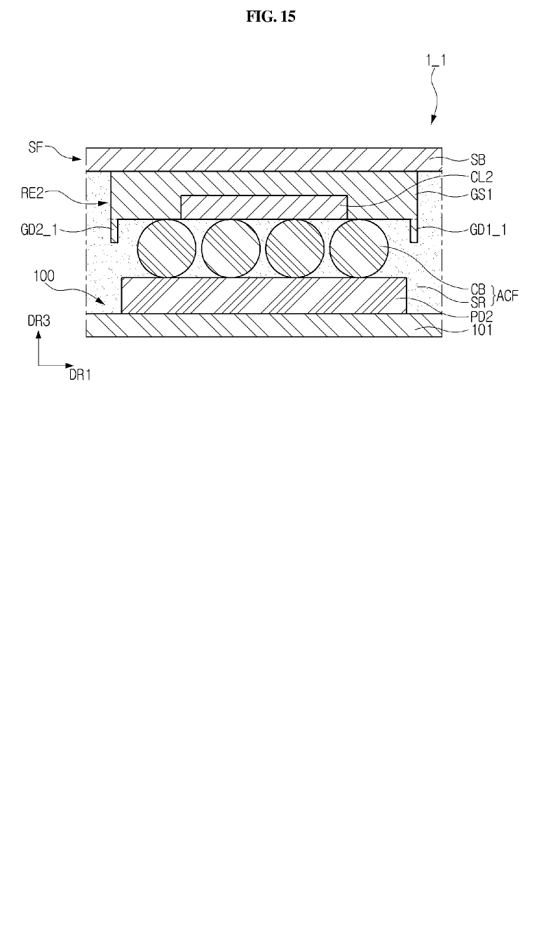

FIG. 15 is a cross-sectional view of a display apparatus according to another embodiment.

Referring to FIG. 15, a display apparatus 1_1 according to the present embodiment may be formed so that the guide portion GD (see FIG. 8) has substantially the same thickness.

FIG. 15 illustrates and describes a first guide portion GD1_1 and a second guide portion GD2_1, but the descriptions thereof may be applied to the third to sixth guide portions GD3 to GD6 (see FIG. 8) in substantially the same manner.

The first guide portion GD1_1 and the second guide portion GD2_1 may protrude from the first base portion GS1 toward the second pad electrode PD2. The first guide portion GD1_1 and the second guide portion GD2_1 may have substantially the same thickness and may not have an inclined surface.

Accordingly, it is possible to further simplify a process of forming the first guide portion GD1_1 and the second guide portion GD2_1, thereby reducing the process cost and process time.

Even in this case, since the visibility of the pressure mark of the conductive ball CB can be improved and the conductive ball CB can be easily collected by the first guide portion GD1_1 and the second guide portion GD2_1, more conductive balls CB may be disposed between the second lead electrode RE and the second pad electrode PD2 so that the second lead electrode RE2 and the second pad electrode PD2 may be electrically connected more easily.

A display apparatus according to various embodiments of the present specification may be described as follows.

According to embodiments of the present specification, there is provided a display apparatus including a display panel including a substrate and a plurality of pads disposed on the substrate, a source film including a source board, and a plurality of leads disposed on the source board and corresponding to the plurality of pads, respectively, and an anisotropic conductive film disposed between the plurality of pads and the plurality of leads, in which the plurality of pads and the plurality of leads are disposed to face each other and overlap each other in a thickness direction, and each of the plurality of leads includes a first base portion and a plurality of guide portions protruding from the first base portion toward the plurality of pads.

According to various embodiments of the present specification, the lead may include a first conductive layer and a second conductive layer different from the first conductive layer.

According to various embodiments of the present specification, the first conductive layer may include a lead groove that is recessed from one surface facing the pad toward the other surface that is a surface opposite to the one surface in the thickness direction, and the second conductive layer may be disposed in the lead groove.

According to various embodiments of the present specification, the first conductive layer may include indium tin oxide (ITO), and the second conductive layer may include copper (Cu).

According to various embodiments of the present specification, the second conductive layer may have a first width in a first direction and extend in a second direction intersecting the first direction, and the first width may range from 24.4 μm to 30.4 μm.

According to various embodiments of the present specification, each of the plurality of guide portions may have a thickness that decreases from an outside of the lead to an inside of the lead.

According to various embodiments of the present specification, each of the plurality of leads may have a width in a first direction and extend in a second direction intersecting the first direction, the plurality of guide portions may include a first guide portion and a second guide portion, and each of the first guide portion and the second guide portion may be disposed on one side surface and the other side surface of the lead in the first direction, respectively, and extend in the second direction.

According to various embodiments of the present specification, the plurality of leads may include a first conductive layer and a second conductive layer surrounded by the first conductive layer, the plurality of guide portions may further include a third guide portion and a fourth guide portion, the second conductive layer may extend in the second direction, and the third guide portion and the fourth guide portion may be disposed at one side and the other side of the second conductive layer in the second direction, respectively.

According to various embodiments of the present specification, the first conductive layer may include the first base portion, the first guide portion, the second guide portion, the third guide portion, and the fourth guide portion, and the first conductive layer and the second conductive layer may be formed of different materials.

According to various embodiments of the present specification, the first base portion, the first guide portion, the second guide portion, the third guide portion, and the fourth guide portion may be formed integrally.

According to various embodiments of the present specification, the display apparatus may further include a plurality of lead lines disposed on the source board, connected to the plurality of leads, respectively, and extending in the second direction, in which the plurality of lead lines may include a second base portion and a fifth guide portion and a sixth guide portion protruding from the second base portion, and the fifth guide portion and the sixth guide portion may be disposed at one side and the other side of the second base portion in the second direction, respectively.

According to various embodiments of the present specification, the first guide portion may be disposed at one side of the first base portion in the second direction, the fifth guide portion may be disposed at one side of the second base portion in the second direction, and the first guide portion and the fifth guide portion may be spaced a predetermined distance from each other.

According to various embodiments of the present specification, the first base portion and the second base portion may include the same material.

According to various embodiments of the present specification, each of the plurality of leads may have a width in the first direction and extend in the second direction intersecting the first direction, and each of the plurality of leads may have a width in the first direction, which decreases in the second direction, at at least one of one side and the other side in the second direction.

According to various embodiments of the present specification, the plurality of leads may be disposed in the first direction, and adjacent leads may be repeatedly disposed in a staggered manner in the second direction intersecting the first direction.

According to embodiments of the present specification, there is provided a display apparatus including a display panel including a substrate and a plurality of pads disposed on the substrate, a source board, a source film disposed on the source board and including a plurality of leads corresponding to the plurality of pads, respectively, and an anisotropic conductive film disposed between the plurality of pads and the plurality of leads, in which the plurality of pads and the plurality of leads are disposed to face each other and overlap each other in a thickness direction, each of the plurality of leads includes a first conductive layer and a second conductive layer different from the first conductive layer, and the first conductive layer includes a lead groove that is recessed from one surface facing the pad toward the other surface that is a surface opposite to the one surface in the thickness direction, and the second conductive layer is disposed in the lead groove.

According to various embodiments of the present specification, the first conductive layer may include indium tin oxide (ITO), and the second conductive layer may include copper (Cu).

According to various embodiments of the present specification, the second conductive layer may have a first width in the first direction and extend in the second direction intersecting the first direction, and the first width may be disposed within a range of 24.4 μm to 30.4 μm.

According to various embodiments of the present specification, the first conductive layer may surround the second conductive layer.

According to various embodiments of the present specification, the first conductive layer may include a base portion and a guide portion protruding from the base portion toward the pad, and the guide portion may have a thickness that decreases from an outside of the lead toward an inside of the lead.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

10: display apparatus

100: display panel

101: substrate

PD: pad electrode (or a pad)

SF: source film

SB: source board

RE: lead electrode (or a lead)

RL: lead line

GS: base portion

GD: guide portion

CL1: first conductive layer

CL2: second conductive layer

ACF: anisotropic conductive film

SR: adhesive member

CB: conductive ball

What is claimed is:

1. A display apparatus comprising:
a display panel including a substrate and a plurality of pads on the substrate;
a source film including a source board and a plurality of leads on the source board, the plurality of leads corresponding to the plurality of pads; and
an anisotropic conductive film between the plurality of pads and the plurality of leads,
wherein the plurality of pads and the plurality of leads face each other and overlap each other in a thickness direction, and
each of the plurality of leads includes a first base portion and a plurality of guide portions protruding from the first base portion toward the plurality of pads.

2. The display apparatus of claim 1, wherein the plurality of leads include a first conductive layer and a second conductive layer that include different materials, and the first base portion and the plurality of guide portions are formed of the first conductive layer.

3. The display apparatus of claim 2, wherein the first conductive layer includes a lead groove that is recessed from a first surface facing a pad from the plurality of pads toward a second surface that is a surface opposite to the first surface in the thickness direction, and the second conductive layer is in the lead groove.

4. The display apparatus of claim 3, wherein the first conductive layer includes indium tin oxide (ITO) and the second conductive layer includes copper (Cu).

5. The display apparatus of claim 4, wherein the second conductive layer has a first width in a first direction and extends in a second direction intersecting the first direction, and the first width is in a range from 24.4 μm to 30.4 μm.

6. The display apparatus of claim 1, wherein each of the plurality of guide portions has a thickness that decreases from an outside of a lead from the plurality of leads to an inside of the lead.

7. The display apparatus of claim 1, wherein each of the plurality of leads has a width in a first direction and extends in a second direction intersecting the first direction,
the plurality of guide portions include a first guide portion and a second guide portion, and
each of the first guide portion and the second guide portion is on a first side surface and a second side surface of a lead from the plurality of leads in the first direction, respectively, and extends in the second direction.

8. The display apparatus of claim 7, wherein the plurality of leads include a first conductive layer and a second conductive layer surrounded by the first conductive layer,
the plurality of guide portions further include a third guide portion and a fourth guide portion,
the plurality of guide portions are formed of the first conductive layer,
the second conductive layer extends in the second direction, and
the third guide portion and the fourth guide portion are at a first side and a second side of the second conductive layer in the second direction, respectively.

9. The display apparatus of claim 8, wherein the first base portion is formed of the first conductive layer, and the first conductive layer and the second conductive layer include different materials.

10. The display apparatus of claim 9, wherein the first base portion, the first guide portion, the second guide portion, the third guide portion, and the fourth guide portion are integral to each other.

11. The display apparatus of claim 7, further comprising:
a plurality of lead lines are on the source board and connected to the plurality of leads, respectively, the plurality of lead lines extending in the second direction,
wherein the plurality of lead lines include a second base portion and a fifth guide portion and a sixth guide portion protruding from the second base portion, and
the fifth guide portion and the sixth guide portion are at a first side and a second side of the second base portion in the second direction, respectively.

12. The display apparatus of claim 11, wherein the first guide portion is at one side of the first base portion in the second direction,
the fifth guide portion is disposed at one side of the second base portion in the second direction, and
the first guide portion and the fifth guide portion are spaced a predetermined distance from each other.

13. The display apparatus of claim 12, wherein the first base portion and the second base portion include a same material.

14. The display apparatus of claim 1, wherein each of the plurality of leads has a width in a first direction and extends in a second direction intersecting the first direction, and
each of the plurality of leads has a width in the first direction, which decreases in the second direction, at at least one of a first side and a second side in the second direction.

15. The display apparatus of claim 14, wherein the plurality of leads are disposed in the first direction, and adjacent leads are repeatedly disposed in a staggered manner in the second direction intersecting the first direction.

16. A display apparatus comprising:
a display panel including a substrate and a plurality of pads on the substrate;
a source film including a source board and a plurality of leads on the source board, the plurality of leads corresponding to the plurality of pads; and
an anisotropic conductive film between the plurality of pads and the plurality of leads,
wherein the plurality of pads and the plurality of leads face each other and overlap each other in a thickness direction,
wherein each of the plurality of leads includes a first conductive layer and a second conductive layer different from the first conductive layer, and
wherein the first conductive layer includes a lead groove that is recessed from a first surface facing a pad from the plurality of pads toward a second surface that is a surface opposite to the first surface in the thickness direction, and the second conductive layer is in the lead groove.

17. The display apparatus of claim 16, wherein the first conductive layer includes indium tin oxide (ITO) and the second conductive layer includes copper (Cu).

18. The display apparatus of claim 17, wherein the second conductive layer has a first width in a first direction and extends in a second direction intersecting the first direction, and the first width is in a range from 24.4 μm to 30.4 μm.

19. The display apparatus of claim 18, wherein the first conductive layer surrounds the second conductive layer.

20. The display apparatus of claim 16, wherein the first conductive layer includes a base portion and a guide portion protruding from the base portion toward the pad, and the guide portion has a thickness that decreases from an outside of a lead from the plurality of leads toward an inside of the lead.
